(19) United States
(12) Patent Application Publication
(10) Pub. No.: US 2024/0397769 A1
(43) Pub. Date: Nov. 28, 2024

(54) DISPLAY DEVICE

(71) Applicant: Sharp Display Technology Corporation, Kameyama City, Mie (JP)

(72) Inventors: Tohru OKABE, Kameyama City (JP); Shoji OKAZAKI, Kameyama City (JP); Shinsuke SAIDA, Kameyama City (JP); Shinji ICHIKAWA, Kameyama City (JP); Hiroki TANIYAMA, Kameyama City (JP); Eiji FUJIMOTO, Kameyama City (JP)

(21) Appl. No.: 18/692,942

(22) PCT Filed: Nov. 2, 2021
(86) PCT No.: PCT/JP2021/040413

§ 371 Date: Mar. 18, 2024

(51) Int. Cl. H10K 59/131; H01L 25/16; H10K 59/35; H10K 59/80; H10K 59/90; H10K 102/00

(52) U.S. Cl. CPC H10K 59/131; H01L 25/167; H10K 59/873; H10K 59/90; H10K 59/35; H10K 2102/311

(57) ABSTRACT

A terminal portion provided in a frame region around a display region is provided with a resin substrate, an inorganic layered film provided above the resin substrate, a pad column provided above the inorganic layered film, the pad column including a plurality of pads arranged in a row electrically connected to a plurality of bumps provided on an IC chip via an ACF, and a flattening film including an organic insulating film provided above the inorganic layered film and the pad column, the flattening film covering an end portion of each of the plurality of pad, and an opening exposing the inorganic layered film is formed in the flattening film.

### TECHNICAL FIELD

The disclosure relates to a display device.

### BACKGROUND ART

In recent years, self-luminous organic electroluminescence (hereinafter also referred to as EL) display devices using organic EL elements attract attention as display devices that can replace liquid crystal display devices. As the organic EL display device, a flexible organic EL display device is proposed that has a flexible panel structure in which an organic EL element constituting a display region, various films, and the like are directly formed on a flexible resin substrate (flexible substrate), and on which an electronic component such as a drive integrated circuit (IC) chip or a flexible printed circuit (FPC) is mounted. For example, the electronic component is connected to an out-of-frame region of a display region of the flexible panel by compression bonding using an anisotropic conductive film (ACF).

For example, PTL 1 discloses a display device including a display region and a terminal region for connecting an electronic component. In this display device, a terminal formed in the terminal region includes a terminal metal, a first oxide conductive film covering an end portion of the terminal metal, and a second oxide conductive film covering the first oxide conductive film and the terminal metal.

### CITATION LIST

### Patent Literature

PTL 1: JP 2018-25671 A

### SUMMARY

### Technical Problem

However, in the display device of PTL 1, since a plurality of oxide conductive films are formed on an upper layer of the terminal metal, the process for manufacturing these upper layers takes a long time, resulting in the inconvenience of increased manufacturing cost.

Regarding this, a flexible organic EL display device has been proposed in which the above-described disadvantage is improved by a process of providing only an organic insulating film on an upper layer of a terminal metal (terminal electrode, pad). In this organic EL display device, although the manufacturing cost is reduced, there is a possibility that deflection occurs in the flexible substrate and cracks occur in the flexible panel due to a high-temperature pressing process used when the electronic component is compression-bonded to the PAD using the ACF.

The disclosure has been made in light of the above-described point, and an object of the disclosure is to reduce cracking occurring in a flexible panel due to a high-temperature pressing process used when mounting an electronic component.

### Solution to Problem

In order to realize this object, a display device according to the disclosure includes: a display region; and a frame region provided around the display region, wherein the frame region is provided with a terminal portion, the terminal portion is provided with a resin substrate, an inorganic layered film including a plurality of inorganic insulating films provided above the resin substrate, a pad column provided above the inorganic layered film, the pad column including a plurality of pads arranged in a row electrically connected to a plurality of bumps provided on an electronic component via an anisotropic conductive film, and a flattening film including an organic insulating film provided above the inorganic layered film and the pad column, the flattening film covering an end portion of each of the plurality of pads, and an opening exposing the inorganic layered film is formed in the flattening film.

### Advantageous Effects of Disclosure

According to the disclosure, it is possible to suppress the occurrence of cracking in a flexible panel caused by a high-temperature pressing process when mounting an electronic component.

### BRIEF DESCRIPTION OF DRAWINGS

FIG. 1 is a plan view illustrating a schematic configuration of an organic EL display device according to a first embodiment of the disclosure.

FIG. 2 is a plan view of a display region of the organic EL display device according to the first embodiment of the disclosure.

FIG. 3 is a cross-sectional view of the display region of the organic EL display device according to the first embodiment of the disclosure.

FIG. 4 is an equivalent circuit diagram of a TFT layer constituting the organic EL display device according to the first embodiment of the disclosure.

FIG. 5 is a cross-sectional view of an organic EL layer constituting the organic EL display device according to the first embodiment of the disclosure.

FIG. 6 is a plan view of a terminal portion (first terminal portion and second terminal portion) in a frame region of the organic EL display device according to the first embodiment of the disclosure.

FIG. 7 is an enlarged plan view of second output pads arranged in the second terminal portion of the organic EL display device according to the first embodiment of the disclosure.

FIG. 8 is a cross-sectional view taken along line VIII-VIII in FIG. 7 illustrating the second terminal portion of the organic EL display device according to the first embodiment of the disclosure.

FIG. 9 is a cross-sectional view taken along line IX-IX in FIG. 7 illustrating a state prior to connection of an electronic component to the second output pads disposed in the second terminal portion of the organic EL display device via an ACF according to the first embodiment of the disclosure.

FIG. 10 is a cross-sectional view taken along line IX-IX in FIG. 7 illustrating movement of an ACF resin upon connection of an electronic component to the second output pads disposed in the second terminal portion of the organic EL display device via an ACF according to the first embodiment of the disclosure.

FIG. 11 corresponds to FIG. 9 and is a cross-sectional view taken along line IX-IX in FIG. 7 illustrating a state prior to connection of an electronic component to the second output pads disposed in the second terminal portion of an organic EL display device via the ACF according to a second embodiment of the disclosure.

FIG. 12 corresponds to FIG. 10 and is a cross-sectional view taken along line IX-IX in FIG. 7 illustrating movement of an ACF resin upon connection of an electronic component to the second output pads disposed in the second terminal portion of an organic EL display device via the ACF according to a second embodiment of the disclosure.

### DESCRIPTION OF EMBODIMENTS

Embodiments of a technique according to the disclosure will be described below in detail with reference to the drawings. Note that the technique according to the disclosure is not limited to the embodiments to be described below.

### First Embodiment

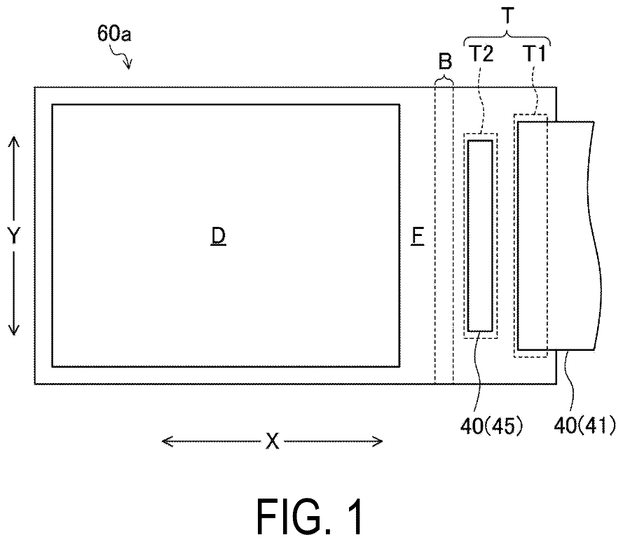

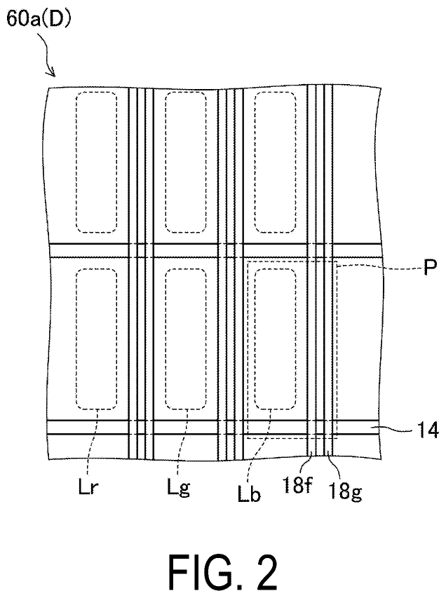

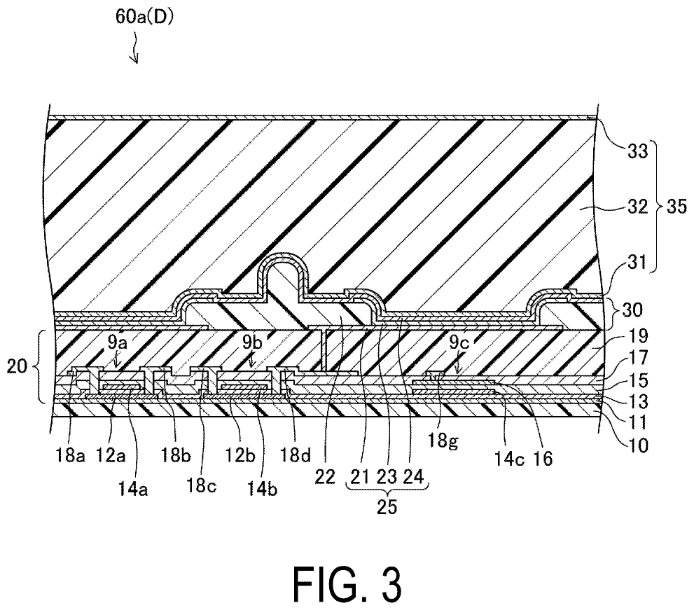

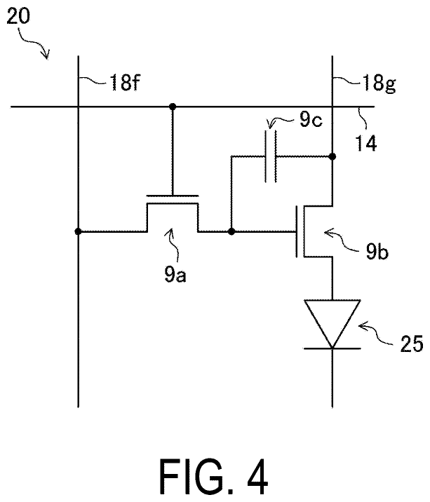

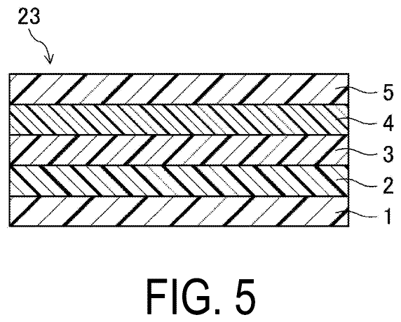

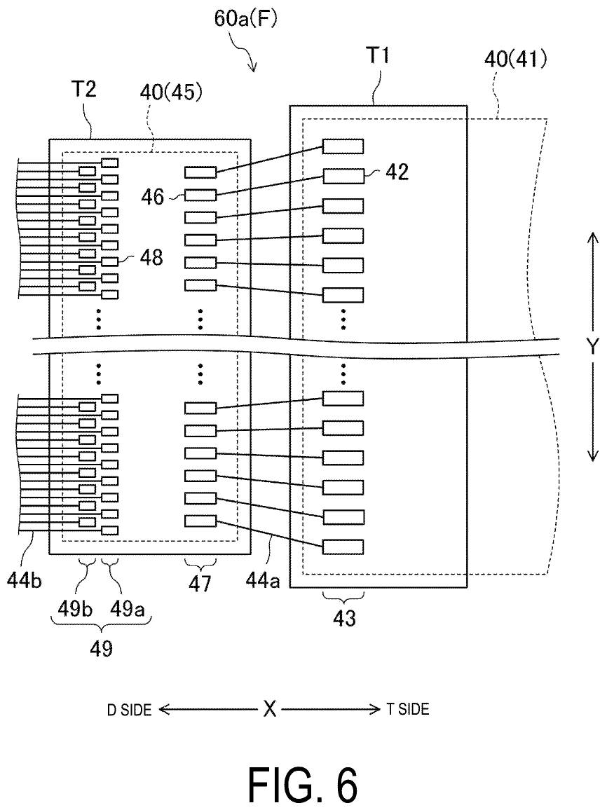

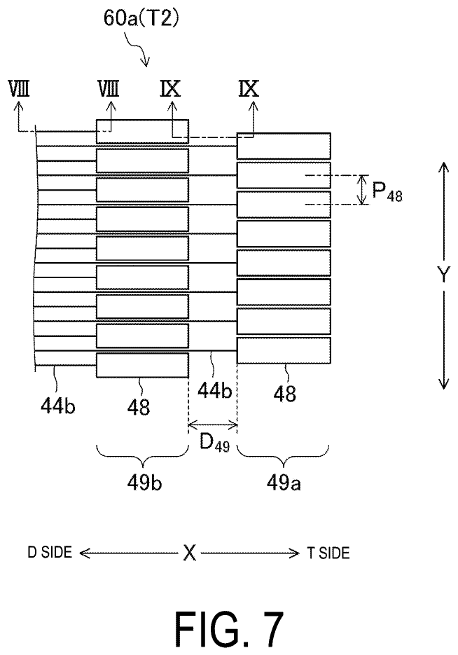

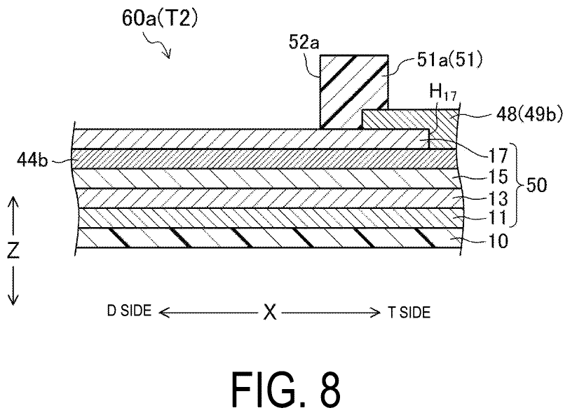

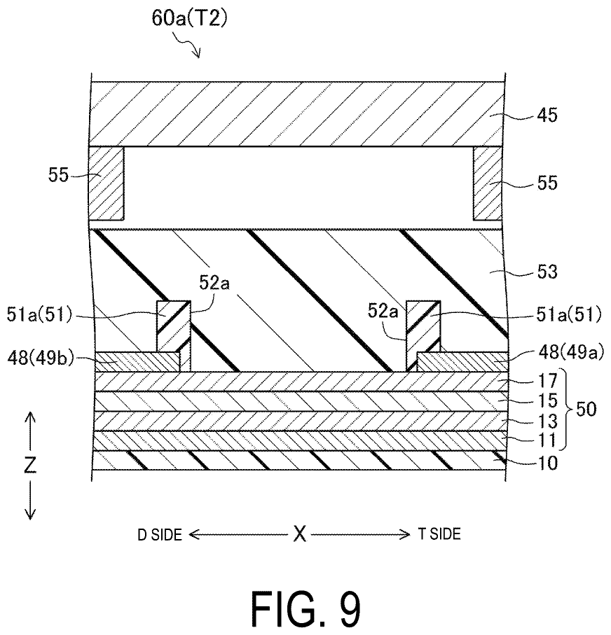

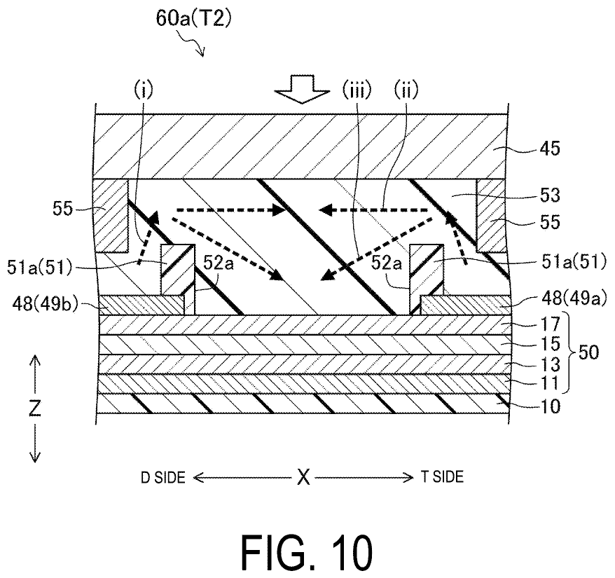

FIGS. 1 to 10 illustrate a first embodiment of a display device according to the disclosure. Note that, in each of the following embodiments, an organic EL display device including an organic EL element will be exemplified as a display device including a light-emitting element. Here, FIG. 1 is a plan view illustrating a schematic configuration of an organic EL display device 60a according to the present embodiment. FIGS. 2 and 3 are a plan view and a cross-sectional view, respectively, of a display region D in the organic EL display device 60a. FIG. 4 is an equivalent circuit diagram of a TFT layer 20 constituting the organic EL display device 60a. FIG. 5 is a cross-sectional view of an organic EL layer 23 constituting the organic EL display device 60a. FIG. 6 is a plan view of a terminal portion T (first terminal portion T1 and second terminal portion T2) in a frame region F of the organic EL display device 60a. FIG. 7 is an enlarged plan view of second output pads 48 arranged in the second terminal portion T2 of the organic EL display device 60a. FIG. 8 is a cross-sectional view taken along line VIII-VIII in FIG. 7 illustrating the second terminal portion T2 of the organic EL display device 60a. FIG. 9 is a cross-sectional view taken along line IX-IX in FIG. 7 illustrating a state prior to connection of an IC chip 45 (electronic component 40) to the second output pads 48 disposed in the second terminal portion T2 of the organic EL display device 60a via an ACF 53. FIG. 10 is a cross-sectional view taken along line IX-IX in FIG. 7 illustrating the movement of the ACF 53 resin when connecting the IC chip 45 to the second output pads 48 disposed in the second terminal portion T2 of the organic EL display device 60a via the ACF 53.

As illustrated in FIG. 1, the organic EL display device 60a includes, for example, a display region D that is provided in a rectangular shape and in which an image is displayed, and the frame region F provided in a frame-like shape around the display region D. Note that in the present embodiment, the display region D having the rectangular shape is exemplified, but the rectangular shape includes a substantial rectangular shape such as a shape whose sides are arc-shaped, a shape whose corners are arc-shaped, and a shape in which a part of a side has a notch. Note that, in the organic EL display device 60a, a direction X parallel to a substrate surface of a resin substrate 10 described below (see FIG. 1 and FIGS. 6 to 10), a direction Y perpendicular to the direction X and parallel to the substrate surface of the resin substrate 10 (see FIGS. 1, 6, and 7), and a direction Z perpendicular to the direction X and the direction Y (see FIGS. 8 to 10) are defined.

As illustrated in FIG. 2, a plurality of subpixels P are arrayed in a matrix shape in the display region D. In addition, in the display region D, for example, a subpixel P including a red light-emitting region Lr for displaying a red color, a subpixel P including a green light-emitting region Lg for displaying a green color, and a subpixel P including a blue light-emitting region Lb for displaying a blue color are provided adjacent to one another, as illustrated in FIG. 2. Note that one pixel is configured by, for example, three adjacent subpixels P including the red light-emitting region Lr, the green light-emitting region Lg, and the blue light-emitting region Lb in the display region D.

In the frame region F, as illustrated in FIG. 1, the first terminal portion T1 is provided at the right end in the diagram extending in the vertical direction (direction Y) in the diagram. An FPC 41 provided as the electronic component 40 is mounted on the first terminal portion T1. Also, in the frame region F, the second terminal portion T2 is provided between the first terminal portion T1 and the display region D extending in the direction Y. The IC chip 45 provided as the electronic component 40 is mounted on the second terminal portion T2. In the present specification, the first terminal portion T1 and the second terminal portion T2 are collectively referred to as the terminal portion T.

In addition, in the frame region F, as illustrated in FIG. 1, a bending portion B that is bendable by 180 degrees (in a U-shape) with the vertical direction (direction Y) in the diagram as a bending axis is provided between the second terminal portion T2 and the display region D extending in the direction Y.

As illustrated in FIG. 3, the organic EL display device 60a includes, in the display region D, the resin substrate 10 (flexible substrate), a thin film transistor (hereinafter, also referred to as a TFT) layer 20 provided on the resin substrate 10, an organic EL element layer 30 provided as a light-emitting element layer constituting the display region D on the TFT layer 20, and a sealing film 35 provided on the organic EL element layer 30. In this manner, the display region D (display panel) of the flexible panel is formed.

The resin substrate 10 is formed of, for example, a polyimide resin.

As illustrated in FIG. 3, the TFT layer 20 includes a base coat film 11 provided on the resin substrate 10, a plurality of first TFTs 9a, a plurality of second TFTs 9b and a plurality of capacitors 9c which are provided on the base coat film 11, and a flattening film 19 provided as a second flattening film on the first TFTs 9a, the second TFTs 9b, and the capacitors 9c. Here, on the TFT layer 20, as illustrated in FIG. 3, the base coat film 11, semiconductor layers 12a and 12b, a gate insulating film 13, a first wiring line layer such as a gate line 14 (see FIG. 2), gate electrodes 14a and 14b, and a lower conductive layer 14c, a first interlayer insulating film 15, second wiring line layer such as an upper conductive layer 16, a second interlayer insulating film 17, a third wiring line layer such as a source line 18f (see FIG. 2), source electrodes 18a and 18c, drain electrodes 18b and 18d, and a power source line 18g, and the flattening film 19 are layered in this order on the resin substrate 10. In addition, on the TFT layer 20, as illustrated in FIGS. 2 and 4, a plurality of the gate lines 14 are provided extending in parallel to one another in the lateral direction in the figures. In addition, a plurality of source lines 18f are provided in the TFT layer 20 to extend in parallel to each other in the vertical direction in the drawings as illustrated in FIGS. 2 and 4. In addition, a plurality of power source lines 18g are provided in the TFT layer 20 to extend in parallel to each other in the vertical direction in the drawings as illustrated in FIGS. 2 and 4. Further, each of the power source lines 18g is provided adjacent to one of the source lines 18f as illustrated in FIG. 2. In the TFT layer 20, as illustrated in FIG. 4, each of the subpixels P is provided with the first TFT 9a, the second TFT 9b, and the capacitor 9c.

Each of the base coat film 11, the gate insulating film 13, the first interlayer insulating film 15, and the second interlayer insulating film 17 is composed of, for example, a single-layer film or a layered film of an inorganic insulating film of silicon nitride (SiNx (x is a positive number)), silicon oxide (SiO₂), silicon oxynitride, or the like. The semiconductor layers 12a and 12b are composed of, for example, a low-temperature polysilicon film, an In—Ga—Zn—O-based oxide semiconductor film, or the like. Each of the first wiring line layer, the second wiring line layer, and the third wiring line layer is formed of, for example, a metal single layer film of a metal such as molybdenum (Mo), titanium (Ti), aluminum (Al), copper (Cu), or tungsten (W), or a metal layered film such as Mo (upper layer)/Al (intermediate layer)/Mo (lower layer), Ti/Al/Ti, Al (upper layer)/Ti (lower layer), Cu/Mo, or Cu/Ti. Note that the third wiring line layer is preferably formed of a metal layered film such as Ti/Al/Ti.

The first TFT 9a and the second TFT 9b are p-type TFTs in which the semiconductor layers 12a and 12b (described later) are doped with a dopant such as boron, for example.

The first TFT 9a is electrically connected to the corresponding gate line 14 and source line 18f in each of the subpixels P, as illustrated in FIG. 4. Additionally, as illustrated in FIG. 3, the first TFT 9a includes a semiconductor layer 12a, the gate insulating film 13, a gate electrode 14a, the first interlayer insulating film 15, the second interlayer insulating film 17, and a source electrode 18a and a drain electrode 18b, which are provided in order on the base coat film 11. Here, the semiconductor layer 12a is provided in an island shape on the base coat film 11 as illustrated in FIG. 3, and has, for example, a channel region, a source region, and a drain region. In addition, as illustrated in FIG. 3, the gate insulating film 13 is provided to cover the semiconductor layer 12a. In addition, the gate electrode 14a is provided on the gate insulating film 13 to overlap the channel region of the semiconductor layer 12a as illustrated in FIG. 3. In addition, the first interlayer insulating film 15 and the second interlayer insulating film 17 are provided in order, covering the gate electrode 14a as illustrated in FIG. 3. In addition, the source electrode 18a and the drain electrode 18b are separated from each other on the second interlayer insulating film 17 as illustrated in FIG. 3. In addition, as illustrated in FIG. 3, the source electrode 18a and the drain electrode 18b are electrically connected to the source region and the drain region of the semiconductor layer 12a, respectively, via contact holes formed in a layered film including the gate insulating film 13, the first interlayer insulating film 15, and the second interlayer insulating film 17.

As illustrated in FIG. 4, the second TFT 9b is electrically connected to the corresponding first TFT 9a and power source line 18g in each of the subpixels P. In addition, as illustrated in FIG. 3, the second TFT 9b includes a semiconductor layer 12b, the gate insulating film 13, a gate electrode 14b, the first interlayer insulating film 15, the second interlayer insulating film 17, and the source electrode 18c and the drain electrode 18d, which are provided in order on the base coat film 11. Here, the semiconductor layer 12b is provided in an island shape on the base coat film 11 as illustrated in FIG. 3, and has, for example, a channel region, a source region, and a drain region. In addition, as illustrated in FIG. 3, the gate insulating film 13 is provided to cover the semiconductor layer 12b. In addition, the gate electrode 14b is provided on the gate insulating film 13 to overlap the channel region of the semiconductor layer 12b as illustrated in FIG. 3. In addition, as illustrated in FIG. 3, the first interlayer insulating film 15 and the second interlayer insulating film 17 are provided in order so as to cover the gate electrode 14b. In addition, the source electrode 18c and the drain electrode 18d are separated from each other on the second interlayer insulating film 17 as illustrated in FIG. 3. In addition, as illustrated in FIG. 3, the source electrode 18c and the drain electrode 18d are electrically connected to the source region and the drain region of the semiconductor layer 12b, respectively, via contact holes formed in a layered film including the gate insulating film 13, the first interlayer insulating film 15, and the second interlayer insulating film 17.

Note that, in the present embodiment, the first TFT 9a and the second TFT 9b are exemplified as being of a top-gate type TFT, but the first TFT 9a and the second TFT 9b may be a bottom-gate type TFT.

The capacitor 9c is electrically connected to the corresponding first TFT 9a and power source line 18g in each of the subpixels P, as illustrated in FIG. 4. Here, as illustrated in FIG. 3, the capacitor 9c includes the lower conductive layer 14c, the first interlayer insulating film 15 provided to cover the lower conductive layer 14c, and the upper conductive layer 16 provided on the first interlayer insulating film 15 to overlap the lower conductive layer 14c. Note that, as illustrated in FIG. 3, the upper conductive layer 16 is electrically connected to the power source line 18g via a contact hole formed in the second interlayer insulating film 17.

The flattening film 19 has a flat surface in the display region D, and is made of, for example, an organic resin material such as a polyimide resin or an acrylic resin, or a polysiloxane-based spin on glass (SOG) material.

As illustrated in FIG. 3, the organic EL element layer 30 includes a plurality of organic EL elements 25 as a plurality of light-emitting elements arrayed in a matrix shape corresponding to the plurality of subpixels P.

As illustrated in FIG. 3, the organic EL element 25 includes a first electrode 21 provided on the flattening film 19 in each of the subpixels P, the organic EL layer 23 provided in each of the subpixels P on the first electrode 21, and a second electrode 24 provided on the organic EL layer 23 commonly to the plurality of subpixels P.

As illustrated in FIG. 3, the first electrode 21 is electrically connected to the drain electrode 18d of the second TFT 9b of each of the subpixels P via a contact hole formed in the flattening film 19. In addition, the first electrode 21 has a function of injecting holes (positive holes) into the organic EL layer 23. In addition, the first electrode 21 is preferably formed of a material with a high work function to improve the efficiency of hole injection into the organic EL layer 23. Here, examples of a material constituting the first electrode 21 include metal materials such as silver (Ag), aluminum (Al), vanadium (V), cobalt (Co), nickel (Ni), tungsten (W), gold (Au), titanium (Ti), ruthenium (Ru), manganese (Mn), indium (In), ytterbium (Yb), lithium fluoride (LiF), platinum (Pt), palladium (Pd), molybdenum (Mo), iridium (Ir), and tin (Sn). Examples of the material constituting the first electrode 21 may include alloys such as astatine (At)/astatine oxide (AtO₂). Furthermore, the material constituting the first electrode 21 may be an electrically conductive oxide, for example, tin oxide (SnO), zinc oxide (ZnO), indium tin oxide (ITO), or indium zinc oxide (IZO). In addition, the first electrode 21 may be formed by layering a plurality of layers formed of any of the materials described above. Note that examples of compound materials having a high work function include indium tin oxide (ITO) and indium zinc oxide (IZO). Furthermore, a peripheral end portion of the first electrode 21 is covered with an edge cover 22 provided in a lattice shape commonly to the plurality of subpixels P. Here, examples of a material constituting the edge cover 22 include a positive photosensitive resin material such as a polyimide resin, an acrylic resin, a polysiloxane resin, and a novolac resin or an SOG material such as polysiloxane.

As illustrated in FIG. 5, the organic EL layer 23 includes a hole injection layer 1, a hole transport layer 2, a light-emitting layer 3, an electron transport layer 4, and an electron injection layer 5 that are sequentially provided on the first electrode 21.

The hole injection layer 1 is also referred to as an anode electrode buffer layer, and has a function of reducing an energy level difference between the first electrode 21 and the organic EL layer 23 to thereby improve the efficiency of hole injection into the organic EL layer 23 from the first electrode 21. Here, examples of materials constituting the hole injection layer 1 include triazole derivatives, oxadiazole derivatives, imidazole derivatives, polyarylalkane derivatives, pyrazoline derivatives, phenylenediamine derivatives, oxazole derivatives, styrylanthracene derivatives, fluorenone derivatives, hydrazone derivatives, and stilbene derivatives.

The hole transport layer 2 has a function of improving the efficiency of hole transport from the first electrode 21 to the organic EL layer 23. Here, examples of materials constituting the hole transport layer 2 include porphyrin derivatives, aromatic tertiary amine compounds, styrylamine derivatives, polyvinylcarbazole, poly-p-phenylenevinylene, polysilane, triazole derivatives, oxadiazole derivatives, imidazole derivatives, polyarylalkane derivatives, pyrazoline derivatives, pyrazolone derivatives, phenylenediamine derivatives, arylamine derivatives, amine-substituted chalcone derivatives, oxazole derivatives, styrylanthracene derivatives, fluorenone derivatives, hydrazone derivatives, stilbene derivatives, hydrogenated amorphous silicon, hydrogenated amorphous silicon carbide, zinc sulfide, and zinc selenide.

The light-emitting layer 3 is a region where holes and electrons are injected from the first electrode 21 and the second electrode 24, respectively, and the holes and the electrons recombine, when a voltage is applied via the first electrode 21 and the second electrode 24. Here, the light-emitting layer 3 is formed of a material having high luminous efficiency. Moreover, examples of the material constituting the light-emitting layer 3 include metal oxinoid compounds (8-hydroxyquinoline metal complexes), naphthalene derivatives, anthracene derivatives, diphenylethylene derivatives, vinyl acetone derivatives, triphenylamine derivatives, butadiene derivatives, coumarin derivatives, benzoxazole derivatives, oxadiazole derivatives, oxazole derivatives, benzimidazole derivatives, thiadiazole derivatives, benzothiazole derivatives, styryl derivatives, styrylamine derivatives, bisstyrylbenzene derivatives, trisstyrylbenzene derivatives, perylene derivatives, perinone derivatives, aminopyrene derivatives, pyridine derivatives, rhodamine derivatives, aquidine derivatives, phenoxazone, quinacridone derivatives, rubrene, poly-p-phenylenevinylene, and polysilane.

The electron transport layer 4 has a function of efficiently transporting electrons to the light-emitting layer 3. Here, examples of materials constituting the electron transport layer 4 include oxadiazole derivatives, triazole derivatives, benzoquinone derivatives, naphthoquinone derivatives, anthraquinone derivatives, tetracyanoanthraquinodimethane derivatives, diphenoquinone derivatives, fluorenone derivatives, silole derivatives, and metal oxinoid compounds, as organic compounds.

The electron injection layer 5 has a function of reducing an energy level difference between the second electrode 24 and the organic EL layer 23 to thereby improve the efficiency of electron injection into the organic EL layer 23 from the second electrode 24, and the electron injection layer 5 can lower the drive voltage of the organic EL element 25 by this function. Note that the electron injection layer 5 is also referred to as a cathode electrode buffer layer. Here, examples of materials constituting the electron injection layer 5 include inorganic alkaline compounds, such as lithium fluoride (LiF), magnesium fluoride (MgF₂), calcium fluoride (CaF₂), strontium fluoride (SrF₂), and barium fluoride (BaF₂), aluminum oxide (Al₂O₃), and strontium oxide (SrO).

As illustrated in FIG. 3, the second electrode 24 is provided to cover the organic EL layer 23 of each of the subpixels P and the edge cover 22. In addition, the second electrode 24 has a function of injecting electrons into the organic EL layer 23. In addition, it is more preferable that the second electrode 24 be formed of a material having a low work function to improve the efficiency of electron injection into the organic EL layer 23. Here, examples of the material constituting the second electrode 24 include silver (Ag), aluminum (Al), vanadium (V), cobalt (Co), nickel (Ni), tungsten (W), gold (Au), calcium (Ca), titanium (Ti), yttrium (Y), sodium (Na), ruthenium (Ru), manganese (Mn), indium (In), magnesium (Mg), lithium (Li), ytterbium (Yb), and lithium fluoride (LiF). The second electrode 24 may also be formed of an alloy such as magnesium (Mg)/copper (Cu), magnesium (Mg)/silver (Ag), sodium (Na)/potassium (K), astatine (At)/astatine oxide (AtO₂), lithium (Li)/aluminum (Al), lithium (Li)/calcium (Ca)/aluminum (Al), and lithium fluoride (LiF)/calcium (Ca)/aluminum (Al), for example. In addition, the second electrode 24 may be formed of conductive oxide, for example, tin oxide (SnO), zinc oxide (ZnO), indium tin oxide (ITO), indium zinc oxide (IZO), or the like. In addition, the second electrode 24 may be formed by layering a plurality of layers formed of any of the materials described above. Note that examples of materials having a low work function include magnesium (Mg), lithium (Li), lithium fluoride (LiF), magnesium (Mg)/copper (Cu), magnesium (Mg)/silver (Ag), sodium (Na)/potassium (K), lithium (Li)/aluminum (Al), lithium (Li)/calcium (Ca)/aluminum (Al), and lithium fluoride (LiF)/calcium (Ca)/aluminum (Al).

As illustrated in FIG. 3, the sealing film 35 is provided on the organic EL element layer 30 to cover each of the organic EL elements 25. Here, as illustrated in FIG. 3, the sealing film 35 includes a first inorganic sealing film 31 provided to cover the second electrode 24, an organic sealing film 32 provided on the first inorganic sealing film 31, and a second inorganic sealing film 33 provided to cover the organic sealing film 32, and has a function of protecting the organic EL layer 23 from moisture, oxygen, and the like. Here, the first inorganic sealing film 31 and the second inorganic sealing film 33 are formed of an inorganic material such as, for example, silicon oxide (SiO₂), aluminum oxide (Al₂O₃), silicon nitride (SiNx (where x is a positive number)) such as trisilicon tetranitride (Si₃N₄), or silicon carbonitride (SiCN). In addition, the organic sealing film 32 is formed of an organic material, for example, an acrylic resin, a polyurea resin, a parylene resin, a polyimide resin, a polyamide resin, or the like.

In the organic EL display device 60a, as illustrated in FIG. 6, the first terminal portion T1 and the second terminal portion T2 are provided as the terminal portion T extending in the direction Y. The first terminal portion T1 and the second terminal portion T2 include a plurality of columns of input and output terminal electrodes (pads) arranged in a pad column. In FIG. 6, the FPC 41 and the IC chip 45 of the electronic component 40 are omitted.

As illustrated in FIG. 6, in the first terminal portion T1, a first pad column 43 in which a plurality of first pads 42 are arranged in a row in the direction Y. The first pad column 43 extends in the direction Y. The plurality of first pads 42 are electrically connected to a plurality of second input pads 46 described below via a plurality of first lead wiring lines 44a. In addition, the plurality of first pads 42 are electrically connected to a plurality of electrodes (not illustrated) provided in the FPC 41 via the ACF 53 described below.

As illustrated in FIGS. 6 and 7, the second terminal portion T2 is provided with a second pad column 47 in which the plurality of second input pads 46 are arranged in a row in the direction Y and a third-a pad column 49a and a third-b pad column 49b (hereinafter, collectively referred to as a third pad column 49) in which the plurality of second output pads 48 are arranged in a zig-zag shape in a plan view in the direction Y. The second pad column 47, the third-a pad column 49a, and the third-b pad column 49b extend in the direction Y. The second pad column 47 and the third pad column 49 are arranged in two rows separated from one another in the direction X in accordance with the size of the IC chip 45 to be mounted. In addition, the third-a pad column 49a and the third-b pad column 49b are arranged in two rows separated from one another in the direction X by about several tens of μm to hundreds of μm. As described above, the plurality of second input pads 46 are electrically connected to the first pads 42 via the plurality of first lead wiring lines 44a. The plurality of second output pads 48 are electrically connected to the first wiring line layer (the gate electrodes 14a and 14b, the lower conductive layer 14c, and the like, see FIG. 3) and the second wiring line layer (the upper conductive layer 16 and the like, see FIG. 3) provided as the plurality of wiring lines in the display region D via second lead wiring lines 44b. The plurality of second input and output pads 46 and 48 are electrically connected to a plurality of input and output bumps provided on the IC chip 45 via the ACF 53.

As illustrated in FIG. 6, the first pad column 43, the second pad column 47, and the third-a pad column 49a and the third-b pad column 49b are separated from one another in the direction X and are arranged in this order from the terminal portion T side (the end portion of the flexible panel) toward the display region D side.

Further, as illustrated in FIG. 6, the second output pads 48 have a smaller area (size) and have a high number of pads compared to the second input pads 46. The second input pads 46 are smaller in size than the first pads 42 but has the same number of pads. Further, the pads 42, 46, and 48 are each formed in a rectangular shape in a plan view. The shape of the pad is not limited to a rectangular shape and may be a polygonal shape, a circular shape, an elliptical shape, or the like in a plan view. The size of the second output pads 48, for example, on short side (the length in the direction Y in FIGS. 6 and 7) is in a range from 4 μm to 20 μm and the long side (the length in the direction X in FIGS. 6 and 7) is in a range from 10 μm to 20 μm. A pitch P₄₈ (see FIG. 7) of the second output pads 48 (an interval between the pads 48 adjacent in the direction Y) is, for example, in a range from 10 μm to 50 μm. A distance D₄₉ (see FIG. 7) between the third-a pad column 49a and the third-b pad column 49b adjacent to one another in the direction X (a distance in the direction X between the adjacent second output pads 48) is, for example, in a range from 20 μm to 100 μm. The size, number, shape, arrangement, and the like of the pads 42, 46, 48 are appropriately determined in accordance with the electronic component 40 and are not particularly limited.

As illustrated in FIGS. 8 to 10, the organic EL display device 60a includes, in the second terminal portion T2, the resin substrate 10, an inorganic layered film 50 provided on the resin substrate 10, the third pad column 49 (second output pads 48) provided on the inorganic layered film 50, and the flattening film 51 provided on the inorganic layered film 50 and the third pad column 49. In the present embodiment, the terminal structure of the third pad column 49 (second output pads 48) in the second terminal portion T2 will be described. However, since the second pad column 47 (second input pads 46) in the second terminal portion T2 and the first pad column 43 (first pads 42) in the first terminal portion T1 have the same terminal structure, a detailed description thereof will be omitted. That is, the same terminal structure can be applied to the terminal portion T of the flexible panel.

As illustrated in FIGS. 8 to 10, the inorganic layered film 50 is formed in the same layer and of the same material as the base coat film 11, the gate insulating film 13, the first interlayer insulating film 15, the second interlayer insulating film 17, and the like as a plurality of inorganic insulating films. The plurality of inorganic insulating films are layered to form the inorganic layered film 50.

As illustrated in FIG. 8, the plurality of second lead wiring lines 44b (in the first terminal portion T1, the first lead wiring lines 44a) are provided on the first interlayer insulating film 15. Further, the second interlayer insulating film 17 is provided on the plurality of second lead wiring lines 44b. In other words, the plurality of second lead wiring lines 44b are interposed between the first interlayer insulating film 15 and the second interlayer insulating film 17 constituting the inorganic layered film 50. The second lead wiring lines 44b are formed in the same layer and of the same material as the second wiring line layer (upper conductive layer 16). Note that the second lead wiring lines 44b may be provided on the gate insulating film 13 (in other words, may be interposed between the gate insulating film 13 and the first interlayer insulating film 15 constituting the inorganic layered film 50). In this case, the second lead wiring lines 44b are formed in the same layer and of the same material as the first wiring line layer (the gate electrodes 14a and 14b, the lower conductive layer 14c, and the like).

As illustrated in FIGS. 8 to 10, the third pad column 49 is provided on the second interlayer insulating film 17 constituting the uppermost layer of the inorganic layered film 50. The third pad column 49 is also provided on the plurality of second lead wiring lines 44b exposed from a contact hole H₁₇ formed in the second interlayer insulating film 17. That is, in the contact hole H₁₇, the plurality of second output pads 48 arranged in the third pad column 49 are in contact with the plurality of second lead wiring lines 44b. Thus, the ends on one side (terminal portion T side) of the plurality of second lead wiring lines 44b are electrically connected to the plurality of second output pads 48 via the contact holes H₁₇. On the other hand, as described above, the ends on the other side (on the display region D side) of the plurality of second lead wiring lines 44b are electrically connected to the plurality of second wiring line layers (or the first wiring line layers) in the display region D and are configured to input and output signals to and from pixel circuits C. That is, the plurality of wiring lines in the display region D and the plurality of second output pads 48 are electrically connected to one another via the plurality of second lead wiring lines 44b.

The second output pads 48 (as with the first pads 42 and the second input pads 46) are formed in the same layer and of the same material as the third wiring line layer (the source electrodes 18a and 18c, the drain electrodes 18b and 18d, the power source line 18g, and the like, see FIG. 3) and a fourth wiring line layer (a conductive layer or the like between the third wiring line layer and the first electrode 21) layered above. The pads 42, 46, and 48 are preferably formed of a metal layered film such as Ti/Al/Ti.

As illustrated in FIGS. 8 to 10, the flattening film 51 is provided on the inorganic layered film 50 (specifically, the second interlayer insulating film 17 constituting the uppermost layer of the inorganic layered film 50) and is provided on the third pad column 49 covering the end portions of the second output pads 48. The flattening film 51 is formed in the same layer and of the same material as the flattening film 19 (second flattening film). That is, the flattening film 51 is formed of an organic insulating film made of a photosensitive organic resin material. As described above, in the organic EL display device 60a, an inorganic insulating film such as an oxide conductive film is not provided above the first pad column 43 (the first pads 42), the second pad column 47 (the second input pads 46), and the third pad column 49 (the second output pads 48), and only an organic insulating film is provided. The thickness (length in the direction Z) of the flattening film 51 is not particularly limited. For example, the thickness of the flattening film 51 above the inorganic layered film 50 is in a range from 2 μm to 4 μm, and the thickness of the flattening film 51 above each pad 42, 46, and 48 is in a range from 1 μm to 3 μm.

Here, in the organic EL display device 60a, as illustrated in FIGS. 8 to 10, an opening 52a that exposes the inorganic layered film 50 (to be specific, the second interlayer insulating film 17 constituting the uppermost layer of the inorganic layered film 50) is formed in the flattening film 51. As illustrated in FIGS. 9 and 10, the opening 52a is formed in the flattening film 51 between the third-a pad column 49a and the third-b pad column 49b separated in the direction X (between the second output pads 48 adjacent in the direction X). In other words, the opening 52a does not overlap each of the second output pads 48 (the third-a pad column 49a and the third-b pad column 49b) in a plan view. In the present embodiment, the flattening film 51 is completely removed (the single opening 52a is formed) between the third-a pad column 49a and the third-b pad column 49b separated in the direction X so that only the flattening film 51 (hereinafter, referred to as a remaining flattening film 51a) covering the end portions of the second output pads 48 exists. In other words, the opening 52a is formed over the entire region between portions of the remaining flattening film 51a. The width (lengths in the direction X) of the remaining flattening film 51a is not particularly limited and may be in a range from 1 μm to 6 μm, for example. The width (length in the direction X) of the opening 52a may be appropriately determined in accordance with the width of the remaining flattening film 51a, the distance D₄₉ between the third-a pad column 49a and the third-b pad column 49b (see FIG. 7), and the like, and may be adjusted to be, for example, equal to or less than the distance D₄₉ minus twice the width of the remaining flattening film 51a.

In FIGS. 8 to 10, the opening 52a is formed in the flattening film 51 between the third-a pad column 49a and the third-b pad column 49b but is not limited thereto. The opening 52a may be formed in the flattening film 51 between pad columns separated from one another by a distance equal to or greater than the width of the opening 52a. For example, the opening 52a may be formed in the flattening film 51 between the first pad column 43 and the second pad column 47 illustrated in FIG. 6 or in the flattening film 51 between the second pad column 47 and the third-a pad column 49a (between the input pad column and the output pad column).

In the second terminal portion T2 configured as described above, the plurality of second output pads 48 are electrically connected to a plurality of output bumps 55 provided on the IC chip 45 via the ACF 53. The connection between the plurality of second input pads 46 in the second terminal portion T2 and the plurality of input bumps (not illustrated) provided on the IC chip 45 and the connection between the plurality of first pads 42 in the first terminal portion T1 and the plurality of electrodes (not illustrated) provided on the FPC 41 have the same configuration, and thus a detailed description thereof will be omitted.

First, as illustrated in FIG. 9, the ACF 53 is bonded onto the second terminal portion T2. The ACF 53 is attached onto the inorganic layered film 50 exposed from the opening 52a, the plurality of second output pads 48 (third pad column 49), and the remaining flattening film 51a covering the entire second terminal portion T2. Note that the thickness of the ACF 53 can be appropriately selected depending on the thickness of the flattening film 51 (remaining flattening film 51a), is not particularly limited, may be in a range from 5 μm to 15 μm. The resin material constituting the ACF 53 is, for example, a thermosetting resin. The size of the metal particles (conductive particles) included in the ACF 53 is in a range from, for example, 0.5 μm to 2 μm. The ACF 53 is not particularly limited, and commercially available products can be used.

Subsequently, as illustrated in FIG. 10, the plurality of second output pads 48 and the plurality of output bumps 55 are compression bonded and connected together by a high-temperature pressing process in the direction indicated by the block arrow. The heating temperature of the ACF 53 during the high-temperature pressing process is not particularly limited and may be, for example, in a range from 100° C. to 200° C. Thus, when the high-temperature pressing process is performed, the resin constituting the ACF 53 is melted and moves in the direction of the broken line arrows illustrated in FIG. 10. Specifically, when the output bumps 55 are pushed to the ACF 53 side, the ACF 53 molten resin present above the second output pads 48 moves through the gaps between the remaining flattening film 51a and the output bumps 55 in the direction indicated by the broken line arrow (i) (diagonally upward) and then further moves between the third-a pad column 49a and the third-b pad column 49b (between the second output pads 48 adjacent to one another in the direction X) in the direction indicated by the broken line arrow (ii) (intermediate portion in the direction X, inward in the direction X).

At this time, in a case where the opening 52a is not formed in the flattening film 51 between the third-a pad column 49a and the third-b pad column 49b, since the flattening film 51 is a relatively thick film having a thickness of several μm, there are few regions where the ACF 53 molten resin that has moved into the intermediate portion in the direction X between the third-a pad column 49a and the third-b pad column 49b can further move (escape to) (the ACF 53 molten resin cannot move much in the direction indicated by the broken line arrow (iii) in FIG. 10). Thus, in the intermediate portion in the direction X between the third-a pad column 49a and the third-b pad column 49b, the ACF 53 molten resin gathers and the amount of the resin increases. As a result, the molten resin expands. Then, stress is applied to the flexible panel side due to the expansion of the ACF 53 resin, and there is a possibility of cracking occurring in the flexible panel. In particular, when the electronic component 40 is the IC chip 45 or the like, since the IC chip 45 itself bends very little even if it is strongly pressed, almost all of the stress caused by the expansion of the ACF 53 resin is applied to the flexible panel side, making cracking in the panel even more likely. In addition, since a photosensitive resin material is used for the organic insulating film constituting the flattening film 51, the organic insulating film is weaker against tensile stress and is more likely to crack than a flexible substrate such as the resin substrate 10. Furthermore, when a crack occurs in the flattening film 51, the crack may progress to the inorganic layered film 50 or the resin substrate 10 located below the flattening film 51.

On the other hand, in the organic EL display device 60a, since the opening 52a is formed between the third-a pad column 49a and the third-b pad column 49b and the flattening film 51 is removed, as illustrated in FIG. 10, the ACF 53 molten resin that have moved between the third-a pad column 49a and the third-b pad column 49b can also move to the region in the opening 52a in the direction (diagonally downward direction) indicated by the broken line arrow (iii). As described above, by increasing the regions where the ACF 53 resin can move, the stress caused by the expansion of the ACF 53 resin is reduced. As a result, since the stress applied to the flexible panel side is also reduced, the occurrence of panel cracking is suppressed. In addition, since the flattening film 51 in which cracks are more likely to occur does not exist in the intermediate portion in the direction X between the third-a pad column 49a and the third-b pad column 49b where expansion of the ACF 53 resin is likely to occur, cracking in the flattening film 51 itself is also suppressed.

### Modified Example of First Embodiment

The opening 52a may be formed at or near the intermediate portion in the direction X between the third-a pad column 49a and the third-b pad column 49b. In this case, the opening 52a may be formed so as to remove the flattening film 51 in a region where expansion of the ACF 53 resin is likely to occur when a high-temperature pressing process is performed. In other words, it is possible to sufficiently leave the remaining flattening film 51a protecting the end faces of the second output pads 48.

In the organic EL display device 60a with the configuration described above, in each of the subpixels P, inputs a gate signal to the first TFT 9a via the gate line 14 to turn on the first TFT 9a, writes a voltage corresponding to a source signal to the gate electrode 14b and the capacitor 9c of the second TFT 9b via the source line 18f, and supplies the organic EL layer 23 with a current from the power source line 18g defined based on the gate voltage of the second TFT 9b, whereby the light-emitting layer 3 of the organic EL layer 23 emits light to display an image. Note that, in the organic EL display device 60a, even when the first TFT 9a is turned off, the gate voltage of the second TFT 9b is held by the capacitor 9c. Thus, the light emission by the light-emitting layer 3 is maintained until a gate signal of the next frame is input.

Next, a method for manufacturing the organic EL display device 60a according to the present embodiment will be described. The method for manufacturing the organic EL display device 60a according to the present embodiment includes a TFT layer forming step, an organic EL element layer forming step, a sealing film forming step, a terminal portion forming step, and an electronic component mounting step.

### TFT Layer Forming Step

### Resin Substrate Forming Step

First, for example, a non-photosensitive polyimide resin (having a thickness of approximately 6 μm) is applied onto a glass substrate, and then the coating film is prebaked and postbaked to form the resin substrate 10.

### Base Coat Film Forming Step

A silicon oxide film (having a thickness of approximately 500 nm) and a silicon nitride film (having a thickness of approximately 100 nm) are sequentially formed, for example, by a plasma chemical vapor deposition (CVD) method, on the resin substrate 10, to form the base coat film 11.

### Semiconductor Layer Forming Step

For example, an amorphous silicon film (having a thickness of approximately 50 nm) is formed on the substrate surface on which the base coat film 11 is formed, by a plasma CVD method, the amorphous silicon film is crystallized by laser annealing or the like to form a semiconductor film of a polysilicon film, and then, the semiconductor film is patterned to form the semiconductor layers 12a and 12b.

### Gate Insulating Film Forming Step

An inorganic insulating film (having a thickness of about 100 nm) such as a silicon oxide film is formed, for example, by plasma CVD, on the substrate surface (entire surface) on which the semiconductor layer 12a and the like is formed, to form the gate insulating film 13.

### First Wiring Line Layer Forming Step

A molybdenum film (about 250 nm in thickness) is formed, by, for example, a sputtering method, on the substrate surface on which the gate insulating film 13 is formed. Then, the molybdenum film is subjected to patterning to form a first wiring line layer including, for example, the gate line 14 and the gate electrodes 14a and 14b. At this time, the lower conductive layer 14c and the like constituting the capacitors 9c are also formed. Note that at this time, the first lead wiring lines 44a and the second lead wiring lines 44b may be formed.

### Doping Step

Thereafter, by doping impurity ions such as boron, for example, using the gate electrodes 14a and 14b as a mask, a portion of each of the semiconductor layers 12a and 12b is made conductive.

### First Interlayer Insulating Film Forming Step

A silicon nitride film (about 100 nm in thickness) is formed, by, for example, a plasma CVD method, on the substrate surface (entire surface) on which at least a part of the semiconductor layer 12a and others is made conductive, thereby forming the first interlayer insulating film 15.

### Second Wiring Line Layer Forming Step

A molybdenum film (having a thickness of approximately 250 nm) is formed by, for example, a sputtering method, on the substrate surface formed with the first interlayer insulating film 15, and then, the molybdenum film is patterned to form the upper conductive layer 16 constituting the capacitors 9c. At this time, the first lead wiring lines 44a and the second lead wiring lines 44b are formed.

### Second Interlayer Insulating Film Forming Step

A silicon oxide film (having a thickness of approximately 300 nm) and a silicon nitride film (having a thickness of approximately 200 nm) are formed in order, by, for example, a plasma CVD method, on the substrate surface formed with the second wiring line layer to form the second interlayer insulating film 17.

### Layered Film Patterning Step

Thereafter, the gate insulating film 13, the first interlayer insulating film 15, and the second interlayer insulating film 17 are patterned to form a contact hole. At this time, at the terminal portion T, a contact hole (the contact hole H₁₇ in the second terminal portion T2 and the like) is formed in the first interlayer insulating film 15 and/or the second interlayer insulating film 17.

### Third Wiring Line Layer Forming Step

A titanium film (having a thickness of approximately 50 nm), an aluminum film (having a thickness of approximately 600 nm), and a titanium film (having a thickness of approximately 50 nm) are sequentially formed, for example, by a sputtering method, on the substrate surface in which the second interlayer insulating film 17 and the above-described contact hole is formed, and then, a metal layered film thereof is patterned to form the source electrodes 18a and 18c, the drain electrodes 18b and 18d, the source line 18f, and the power source line 18g. At this time, the first pads 42 (first pad column 43) are formed on the substrate surface in the first terminal portion T1, and the second input pads 46 (second pad column 47) and the second output pads 48 (third-a pad column 49a and third-b pad column 49b) are formed on the substrate surface in the second terminal portion T2.

### Flattening Film Forming Step

Finally, a photosensitive polyimide resin (about 2.5 μm in thickness) is applied, by, for example, a spin coating method or a slit coating method, onto the substrate surface on which the third wiring line layer is formed, and then the coating film is pre-baked, exposed, developed, and post-baked to form the flattening film 19. At this time, the flattening film 51 is formed on the substrate surface in the terminal portion T.

In the above-described manner, the TFT layer 20 can be formed.

### Organic EL Element Layer Forming Step

On the flattening film 19 of the TFT layer 20 formed in the TFT layer forming step, the first electrode 21, the edge cover 22, the organic EL layer 23 (the hole injection layer 1, the hole transport layer 2, the light-emitting layer 3, the electron transport layer 4, and the electron injection layer 5), and the second electrode 24 are formed using a known method, thereby forming the organic EL element 25 and forming the organic EL element layer 30.

### Sealing Film Forming Step

On the organic EL element layer 30 formed in the organic EL element layer forming step, an inorganic insulating film such as a silicon nitride film, a silicon oxide film, or a silicon oxynitride film is formed by a plasma CVD method using a mask to cover each of the organic EL elements 25, thereby forming the first inorganic sealing film 31.

Subsequently, an organic resin material such as an acrylic resin is formed on the first inorganic sealing film 31 by, for example, an inkjet method to form the organic sealing film 32.

Thereafter, an inorganic insulating film such as a silicon nitride film, a silicon oxide film, or a silicon oxynitride film is formed by a plasma CVD method using a mask to cover the organic sealing film 32 to form the second inorganic sealing film 33, thereby forming the sealing film 35.

### Terminal Portion Forming Step

The opening 52a is formed in the flattening film 51 formed in the flattening film forming step in the TFT layer forming step described above. To be more specific, the flattening film 51 between the third-a pad column 49a and the third-b pad column 49b formed in the third wiring line layer forming step in the TFT layer forming step is removed by, for example, photolithography or the like to leave only the flattening film 51 (remaining flattening film 51a) covering the end portions of the second output pads 48 arranged in the third-a pad column 49a and the third-b pad column 49b. The opening 52a may also be formed as described above in the flattening film 51 between the first pad column 43 and the second pad column 47 and/or in the flattening film 51 between the second pad column 47 and the third-a pad column 49a.

### Electronic Component Mounting Step

First, the ACF 53 is bonded so as to cover the substrate surfaces of the first terminal portion T1 and the second terminal portion T2 formed in the terminal portion forming step described above.

Subsequently, in the first terminal portion T1, the first pads 42 arranged in the first pad column 43 and the electrodes (not illustrated) provided in the FPC 41 are thermocompression-bonded by a high-temperature pressing process and electrically connected to one another through the ACF 53. In the second terminal portion T2, the second input pads 46 arranged in the second pad column 47 and the input bumps (not illustrated) provided on the IC chip 45 and the second output pads 48 arranged in the third pad column 49 and the output bumps 55 provided on the IC chip 45 are thermocompression-bonded by a high-temperature pressing process and electrically connected to one another through the ACF 53.

Finally, after a protective sheet (not illustrated) is applied to the substrate surface, the glass substrate is peeled off from the lower face of the resin substrate 10 by irradiation with laser light from the glass substrate side of the resin substrate 10, and then a protective sheet (not illustrated) is applied to the lower face of the resin substrate 10, from which the glass substrate has been peeled off.

Thus, the organic EL display device 60a of the present embodiment can be manufactured as described above.

### Effect

As described above, according to the organic EL display device 60a according to the present embodiment and the modified example thereof, the following effects can be obtained.

In the organic EL display device 60a, in the terminal portion T connecting to the electronic component 40 via the ACF 53, only the flattening film 51 formed of an organic insulating film is provided as an upper layer of the pads, 42, 46, and 48 (pad columns 43, 47, 49), and the opening 52a exposing the inorganic layered film 50, which is a lower layer of the pads 42, 46, and 48, is formed in the flattening film 51. Thus, the ACF 53 resin melted in the high-temperature pressing process can move in the opening 52a region (region where the flattening film 51 is removed). That is, since a movement region for the ACF 53 resin is secured (increased), it is possible to reduce the stress caused by the flow of the ACF 53 resin when the electronic component 40 is pushed in, and as a result, it is also possible to reduce the stress applied to the flexible panel. In addition, by removing a portion of the flattening film 51 where stress may be applied (the flattening film 51 between (an intermediate portion of) adjacent pad columns), it is possible to suppress occurrence of cracking in the flattening film 51 itself, and as a result, it is also possible to suppress progression of cracking to the inorganic layered film 50 and the resin substrate 10 in the lower layers. As described above, it is possible to suppress the occurrence of cracking in the flexible panel caused by the high-temperature pressing process when mounting the electronic component 40.

In the organic EL display device 60a, the flattening film 51 where the opening 52a is formed remains covering the end faces of the pads 42, 46, and 48. Since the remaining flattening film 51a is provided as an edge cover, corrosion of the end faces of the pads 42, 46, and 48 can be suppressed. Specifically, when each pad 42, 46, and 48 is formed of a metal layered film such as Ti/Al/Ti, for example, Al corrosion can be suppressed.

### Second Embodiment

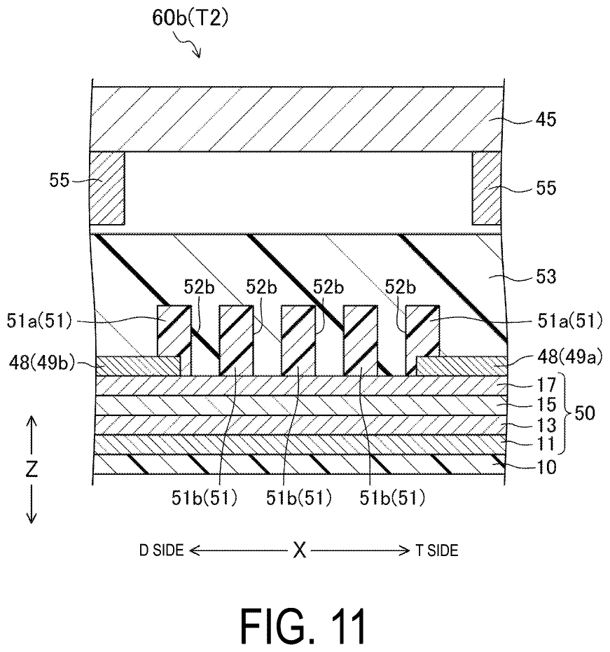

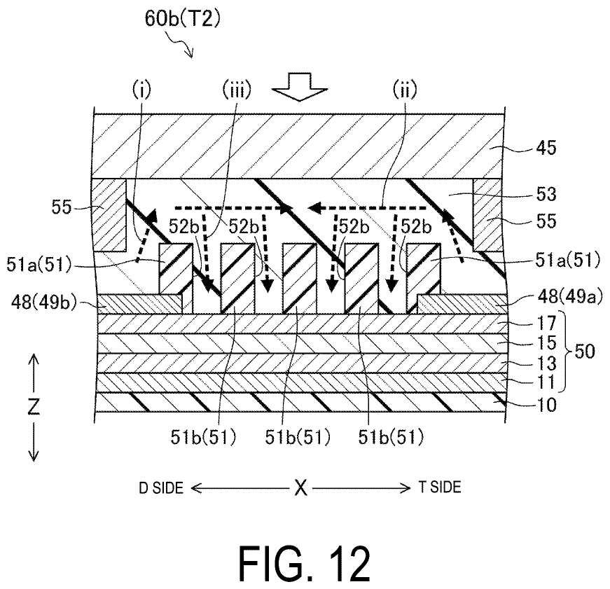

Next, a second embodiment of the disclosure will be described. FIGS. 11 and 12 illustrate a second embodiment of the display device according to the disclosure. FIG. 11 corresponds to FIG. 9 and is a cross-sectional view taken along line IX-IX in FIG. 7 illustrating a state prior to connection of the IC chip 45 (electronic component 40) to the second output pads 48 disposed in the second terminal portion T2 of an organic EL display device 60b of the present embodiment via the ACF 53. FIG. 12 corresponds to FIG. 10 and is a cross-sectional view taken along line IX-IX in FIG. 7 illustrating the movement of the ACF 53 resin when connecting the IC chip 45 to the second output pads 48 disposed in the second terminal portion T2 of the organic EL display device 60b via the ACF 53.

The entire configuration of the organic EL display device 60b is the same as that of the first embodiment described above other than the configuration of the terminal portion T, and thus detailed description thereof will be omitted. Note that constituent portions similar to those in the first embodiment are denoted by the same reference signs, and a description thereof will be omitted. In the present embodiment, the terminal structure of the third pad column 49 (second output pads 48) in the second terminal portion T2 will be described. However, since the second pad column 47 (second input pads 46) in the second terminal portion T2 and the first pad column 43 (first pads 42) in the first terminal portion T1 have the same terminal structure, a detailed description thereof will be omitted. That is, the same terminal structure can be applied to the terminal portion T of the flexible panel.

Between the third-a pad column 49a and the third-b pad column 49b separated from one another in the direction X (between the second output pads 48 adjacent in the direction X), in the organic EL display device 60a according to the first embodiment, all of the flattening film 51 other than the remaining flattening film 51a is removed and the single opening 52a is formed. However, in the organic EL display device 60b according to the present embodiment, as illustrated in FIGS. 11 and 12, a plurality of openings 52b (four in FIGS. 11 and 12) are formed. To be specific, each of the plurality of openings 52b is formed in a slit shape linearly extending in the direction Y of the third pad column 49. The slit-shaped openings 52b are separated from one another in the direction X. The flattening film 51 remaining between the slit-shaped openings 52b adjacent to one another in the direction X (hereinafter, also referred to as a slit-shaped flattening film 51b) also has a slit shape linearly extending in the direction Y.

The width (length in the direction X) of the slit-shaped flattening film 51b is not particularly limited and may be in a range from 1 μm to 6 μm, for example. The width (length in the direction X) of the slit-shaped openings 52b may be appropriately adjusted in accordance with the width of the slit-shaped flattening film 51b, the number of slit-shaped openings 52b (slit-shaped flattening films 51b), and the like. The width and height of the remaining flattening films 51a covering the end portions of the second output pads 48 are the same as those in the first embodiment.

### Modified Example of Second Embodiment

The plurality of slit-shaped openings 52b (the slit-shaped flattening film 51b remaining between the slit-shaped openings 52b) may be formed so as to linearly extend in the direction X orthogonal to the direction Y in the length in the direction Y of the third pad column 49 (between the second output pads 48 at both ends in the direction Y). In this case, the slit-shaped openings 52b are provided separated from one another in the direction Y.

The organic EL display device 60b according to the present embodiment and the modified example thereof can be manufactured using the terminal portion forming step in the manufacturing method of the organic EL display device 60a according to the first embodiment by modifying the pattern shape used when removing the flattening film 51 and forming the opening 52a.

### Effect

As described above, according to the organic EL display device 60b according to the present embodiment and the modified example thereof, effects similar to those described above can be obtained. To be specific, in the organic EL display device 60b, the plurality of openings 52b are provided, and the plurality of openings 52b are formed in a slit shape. That is, the flattening film 51 between the adjacent pad columns is not entirely removed except for the remaining flattening film 51a covering the end faces of the pads 42, 46, and 48 and is only partially removed. As a result, as illustrated in FIG. 12, the ACF 53 molten resin that have moved between the third-a pad column 49a and the third-b pad column 49b moves in the direction indicated by the broken line arrow (iii) (downward) toward a region in the plurality of slit-shaped openings 52b during the (path of) movement in the direction indicated by the broken line arrow (ii). Thus, when the electronic component 40 is pushed in, the ACF 53 resin moves slowly in the direction indicated by the broken line arrow (ii) (the ACF 53 resin gradually flows). Accordingly, the concentration of stress caused by the flow of the ACF 53 resin when the electronic component 40 is pushed in can be alleviated, and as a result, it is possible to reduce the stress applied to the flexible panel. In addition, by forming the flattening film 51 in a slit shape, it is possible to suppress the occurrence of cracking in the slit-shaped flattening film 51b itself.

Further, as illustrated in FIGS. 11 and 12, when the plurality of slit-shaped openings 52b are formed extending in the short side direction Y of the pads 42, 46, and 48 (the direction of the pad columns 43, 47, and 49), the density of the slit-shaped flattening film 51b can be made uniform, so that the uniformity of warpage of the flexible substrate can be enhanced.

### OTHER EMBODIMENTS

Although the organic EL layer having a five-layer structure including the hole injection layer, the hole transport layer, the light-emitting layer, the electron transport layer, and the electron injection layer has been exemplified in each of the embodiments described above, the organic EL layer may have a three-layer structure including a hole injection-cum-transport layer, a light-emitting layer, and an electron transport-cum-injection layer, for example.

In each of the embodiments described above, the organic EL display device including the first electrode as an anode and the second electrode as a cathode is exemplified. The disclosure is also applicable to an organic EL display device in which the layered structure of the organic EL layer is reversed with the first electrode being a cathode and the second electrode being an anode.

In each of the embodiments described above, the organic EL display device in which the electrode of the TFT connected to the first electrode serves as the drain electrode is exemplified. However, the disclosure is also applicable to an organic EL display device in which the electrode of the TFT connected to the first electrode is referred to as the source electrode.

In each of the embodiments described above, the organic EL display device is exemplified as the disclosure, but the disclosure is also applicable to a display device such as a liquid crystal display device employing an active matrix driving method.

In addition, in each of the embodiments described above, the organic EL display device is exemplified and described as a display device. The disclosure is also applicable to a display device including a plurality of light-emitting elements that are driven by an electrical current. For example, the disclosure is applicable to a display device including quantum-dot light emitting diodes (QLEDs) that are light-emitting elements using a quantum dot-containing layer.

### INDUSTRIAL APPLICABILITY

As described above, the disclosure is useful for a flexible display device.

1: A display device comprising:
a display region; and
a frame region provided around the display region,
wherein the frame region is provided with a terminal portion,
the terminal portion is provided with
a resin substrate,
an inorganic layered film including a plurality of inorganic insulating films provided above the resin substrate,
a pad column provided above the inorganic layered film, the pad column including a plurality of pads arranged in a row electrically connected to a plurality of bumps provided on an electronic component via an anisotropic conductive film, and
a flattening film including an organic insulating film provided above the inorganic layered film and the pad column, the flattening film covering an end portion of each of the plurality of pads, and
an opening exposing the inorganic layered film is formed in the flattening film.

2: The display device according to claim 1,
wherein the opening does not overlap each of the plurality of pads in a plan view.

3: The display device according to claim 1,
wherein the opening is formed across an entire region between portions of the flattening film covering the end portion of each of the plurality of pads.

4: The display device according to claim 1,
wherein a plurality of the openings are formed.

5: The display device according to claim 4,
wherein each of the plurality of openings is formed in a slit shape extending in a direction of the pad column.

6: The display device according to claim 1,
wherein a plurality of the pad columns are provided separated from one another, and
the opening is formed between the plurality of the pad columns.

7: The display device according to claim 6,
wherein the plurality of the pad columns are two pad columns in which the plurality of pads are arranged in a zig-zag shape in a plan view.

8: The display device according to claim 6,
wherein a distance between the plurality of the pad columns is in a range from 20 μm to 100 μm.

9: The display device according to claim 1,
wherein a width of the flattening film covering the end portion of each of the plurality of pads is in a range from 1 μm to 6 μm.

10: The display device according to claim 1,
wherein a thickness of the flattening film located above each of the plurality of pads is in a range from 1 μm to 3 μm.

11: The display device according to claim 1,
wherein a thickness of the flattening film located above the inorganic layered film is in a range from 2 μm to 4 μm.

12: The display device according to claim 1,
wherein each of the plurality of pads is formed of a metal layered film of Ti/Al/Ti.

13: The display device according to claim 1,
wherein the electronic component is an IC chip.

14: The display device according to claim 1,
wherein the display region is provided with
the resin substrate,
a thin film transistor layer provided above the resin substrate with a thin film transistor disposed at each of a plurality of subpixels, the thin film transistor layer including a semiconductor layer, a gate insulating film, a first wiring line layer, a first interlayer insulating film, a second wiring line layer, a second interlayer insulating film, a third wiring line layer, and a second flattening film layered in this order,
a light-emitting element layer provided above the thin film transistor layer with a plurality of light-emitting elements disposed at each of the plurality of subpixels, and
a sealing film provided covering the light-emitting element layer.

15: The display device according to claim 14,
wherein the inorganic layered film includes at least one layer of the gate insulating film, the first interlayer insulating film, or the second interlayer insulating film.

16: The display device according to claim 14, further comprising:
a plurality of lead wiring lines interposed in the inorganic layered film,
wherein each of the plurality of lead wiring lines is formed in the same layer and of the same material as the first wiring line layer and/or the second wiring line layer.

17: The display device according to claim 16,
wherein the plurality of lead wiring lines are electrically connected to the plurality of pads via a contact hole formed in the inorganic layered film above the lead wiring lines.

18: The display device according to claim 14,
wherein each of the plurality of pads is formed in the same layer and of the same material as the third wiring line layer.

19: The display device according to claim 14,
wherein the flattening film is formed in the same layer and of the same material as the second flattening film.

20: The display device according to claim 14,
wherein each of the plurality of light-emitting elements is an organic electroluminescence element.
